(19) United States
(12) Patent Application Publication
(10) Pub. No.: US 2015/0333041 A1
(43) Pub. Date: Nov. 19, 2015

(54) SEMICONDUCTOR DEVICE AND MANUFACTURING METHOD THEREFOR

(71) Applicant: PS5 Luxco S.a.r.l., Luxembourg (LU)

(72) Inventor: Atsushi Tomohiro, Tokyo (JP)

(21) Appl. No.: 14/655,209

(22) PCT Filed: Dec. 19, 2013
(86) PCT No.: PCT/JP2013/084037

§ 371 Date: Jun. 24, 2015

(30) Foreign Application Priority Data
Dec. 25, 2012 (JP) 2012-280972

(51) Int. Cl. H01L 25/065; H01L 23/00; H01L 23/492; H01L 23/29; H01L 23/498; H01L 25/00; H01L 23/31

(52) U.S. Cl. CPC H01L 25/0657; H01L 25/50; H01L 24/30; H01L 23/3114; H01L 23/293; H01L 24/49; H01L 24/85; H01L 23/49838; H01L 24/73; H01L 23/4926; H01L 2225/0651; H01L 2225/06562; H01L 2924/01014; H01L 2224/33181; H01L 2224/32145; H01L 2224/48106; H01L 2224/48227; H01L 2224/73265; H01L 2924/1511

(57) ABSTRACT

One semiconductor device includes a circuit board on which multiple connection pads are formed, a first semiconductor chip that is mounted on the circuit board, a second semiconductor chip that is laminated on the first semiconductor chip and has multiple electrodes, reinforcement plates that are laminated on the second semiconductor chip, and multiple wires that electrically connect the multiple connection pads and the multiple electrodes together, wherein the second semiconductor chip has a laminated area that overlaps with the first semiconductor chip and overhang areas that overhang from the first semiconductor chip, the electrodes are formed in the overhang areas, and the reinforcement plates are laminated on the second semiconductor chip so as to straddle the laminated area and the respective overhang areas of the second semiconductor chip.

### TECHNICAL FIELD

The present invention relates to a semiconductor device and a method for producing same, and in particular the present invention relates to a semiconductor device in which a plurality of semiconductor chips are stacked on a wiring board, and a method for producing same.

### BACKGROUND

An MCP (multi-chip package) semiconductor device fitted with a plurality of semiconductor chips and having a structure in which an overhang region of an upper-stage semiconductor chip is supported by means of a bump or a wire is known in the art (see Patent Documents 1-3, for example).

### PATENT DOCUMENTS

Patent Document 1: JP 2009-099697 A

Patent Document 2: JP 2009-194189 A

Patent Document 3: JP 2011-086943 A

### SUMMARY OF THE INVENTION

### Problem to be Solved by the Invention

However, semiconductor devices continue to become thinner as mobile devices become more compact and thinner themselves, and it has become necessary to make the semiconductor chips mounted in semiconductor devices thinner. When the thickness of an upper-stage semiconductor chip is reduced in the conventional technology, the load from wire bonding an electrode formed in an overhang region of the upper-stage semiconductor chip is not supported by a bump or a wire and there is a risk that it will no longer be possible to achieve a satisfactory wire connection, which is problematic.

The present invention is intended to solve the problems of the prior art, which is to say that the aim of the present invention lies in providing a semiconductor device which achieves satisfactory wire bonding, and a method for producing same.

### Means for Solving the Problem

A semiconductor device according to the present invention solves the abovementioned problem by virtue of the fact that it comprises: a wiring board on which a plurality of connection pads are formed; a first semiconductor chip mounted on the wiring board; a second semiconductor chip which is stacked on the first semiconductor chip and comprises a plurality of electrodes; a reinforcing plate which is stacked on the second semiconductor chip; and a plurality of wires for electrically connecting the plurality of connection pads and the plurality of electrodes, the second semiconductor chip comprising a stack region which lies over the first semiconductor chip, and an overhang region which overhangs the first semiconductor chip, the electrodes being formed in the overhang region, and the reinforcing plate being stacked on the second semiconductor chip in such a way as to lie across the stack region and the overhang region of the second semiconductor chip.

The method for producing a semiconductor device according to the present invention solves the abovementioned problem by virtue of the fact that it comprises the following steps: a step in which a wiring board formed with a plurality of connection pads is prepared; a step in which a first semiconductor chip is mounted on the wiring board; a step in which a second semiconductor chip on which electrodes are formed is mounted on the first semiconductor chip in such a way that a portion of the second semiconductor chip overhangs the first semiconductor chip; a step in which a reinforcing plate is mounted on the second semiconductor chip in such a way as to lie across a stack region of the second semiconductor chip which lies over the first semiconductor chip and an overhang region of the second semiconductor chip which overhangs the first semiconductor chip; and a step in which the plurality of connection pads and the plurality of electrodes are electrically connected by means of wires.

### Advantage of the Invention

According to the present invention, a reinforcing plate is stacked on a second semiconductor chip in such a way as to lie across a stack region and an overhang region of the second semiconductor chip, and as a result it is possible to increase the essential thickness of the overhang region of the second semiconductor chip and to increase the rigidity of the overhang region of the second semiconductor chip, so there is no cracking of the chip and no sections which are not wire-bonded, a load or ultrasonic waves can be satisfactorily applied to the electrodes formed in the overhang region of the second semiconductor chip, and satisfactory wire bonding can be achieved.

### BRIEF DESCRIPTION OF THE FIGURES

FIG. 1 is a plan view showing a semiconductor device according to a first mode of embodiment of the present invention;

FIG. 2 is a view in cross section showing the semiconductor device at the position of the line A-A′ in FIG. 1;

FIG. 3 is a process diagram showing the steps of producing the semiconductor device according to the first mode of embodiment;

FIG. 4 is a process diagram showing the steps for producing the semiconductor device following FIG. 3;

FIG. 5 is a view in cross section showing a semiconductor device according to a first variant example of the first mode of embodiment;

FIG. 6 is a view in cross section showing a semiconductor device according to a second variant example of the first mode of embodiment;

FIG. 7 is a view in cross section showing a semiconductor device according to a third variant example of the first mode of embodiment;

FIG. 8 is a view in cross section showing the semiconductor device at the position of the line A-A′ in FIG. 7;

FIG. 9 is a process diagram showing the steps for producing a semiconductor device according to a fourth variant example of the first mode of embodiment;

FIG. 10 is a plan view showing a semiconductor device according to a second mode of embodiment of the present invention; and

FIG. 11 is a view in cross section showing the semiconductor device at the position of the line A-A′ in FIG. 10.

### MODE OF EMBODIMENT OF THE INVENTION

A number of modes of embodiment and variant examples of the semiconductor device according to the present invention will be described below with reference to the figures.

It should be noted that in the following description, a first direction X is defined as a direction parallel to a wiring board, a second direction Y is defined as a direction orthogonal to the first direction X and parallel to the wiring board, and a third direction Z is defined as a direction perpendicular to the wiring board.

### Exemplary Embodiment

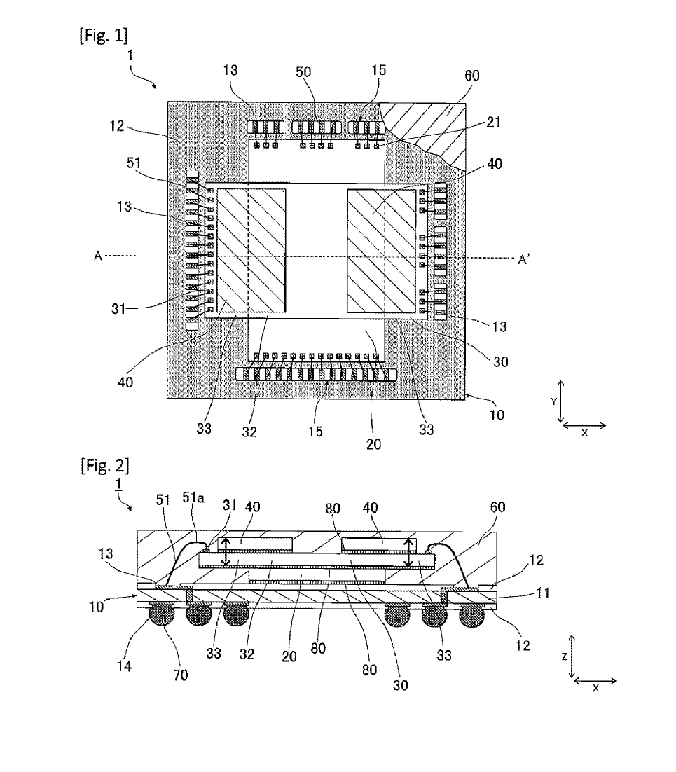

A semiconductor device 1 relating to a first mode of embodiment of the present invention will be described with reference to FIGS. 1-4.

The semiconductor device 1 according to the first mode of embodiment is constructed as an MCP semiconductor device, and as shown in FIGS. 1 and 2, it comprises: a wiring board 10; a first semiconductor chip 20 such as a DRAM memory chip; a second semiconductor chip 30 such as a DRAM memory chip; a silicon substrate 40 serving as a reinforcing plate; first wires 50; second wires 51; sealing resin 60; and external terminals 70.

As shown in FIGS. 1 and 2, the wiring board 10 comprises: an insulating base material 11 which is formed from glass epoxy for example, and is formed in the shape of a substantially square plate; a wiring layer (not depicted) which is patterned on both surfaces of the insulating base material 11; and an insulating film 12 which is formed in such a way as to cover the wiring layer.

A plurality of connection pads 13 are connected to and formed on the wiring layer on one side of the wiring board 10. Furthermore, a plurality of lands 14 are connected to and formed on the wiring layer on the other side of the wiring board 10. The plurality of connection pads 13 are formed in an array in the vicinity of the peripheral edges of one surface of the wiring board 10, as shown in FIG. 1. Furthermore, the plurality of lands 14 are arranged in the form of a grid on the other surface of the wiring board 10. The plurality of connection pads 13 and the plurality of lands 14 are connected to one another by means of contiguous wiring and vias or the like passing through the insulating base material 11. The wires 50, 51 are connected to the connection pads 13 and the external terminals 70 are mounted on the lands 14.

The insulating film 12 is a solder resist (SR), for example. The insulating film 12 is formed over the whole of both surfaces of the wiring board 10 excluding a predetermined region or predetermined regions. In other words, the insulating film 12 is partially removed in relation to a predetermined region or predetermined regions so that there is at least one opening in the insulating film 12. For example, openings 15 are formed in one surface of the wiring board 10. The openings 15 expose the regions in which the plurality of connection pads 13 are formed and the surrounding region. Openings which expose the plurality of lands 14 are also formed in the other surface of the wiring board 10.

As shown in FIG. 1, the first semiconductor chip 20 is formed in the shape of a substantially rectangular plate and is mounted on one surface of the wiring board 10 with the lengthwise direction thereof lying in the second direction Y. The other surface of the semiconductor chip 20 is fixedly bonded by means of an adhesive member 80 such as a DAF (die attach film) to the region of the wiring board 10 in which the insulating film 12 is formed.

A predetermined circuit (not depicted) and first electrode pads 21 are formed on one surface of the first semiconductor chip 20. The plurality of electrode pads 21 are formed in an array along the short sides of the first semiconductor chip 20, as shown in FIG. 1. The first electrode pads 21 and the connection pads 13 are connected by means of the first wires 50, as shown in FIG. 1.

As shown in FIG. 1, the second semiconductor chip 30 is formed in the shape of a substantially rectangular plate and is stacked on one surface of the first semiconductor chip 20 with the lengthwise direction thereof lying along the first direction. As shown in FIG. 1, the second semiconductor chip 30 is arranged in such a way as not to cover the regions of the first semiconductor chip 20 in which the first electrode pads 21 are formed, and as a result both ends of the second semiconductor chip 30 in the first direction X form an overhang (i.e., project) outside the first semiconductor chip 20. By this means, a stack region 32 which lies over the first semiconductor chip 20, and overhang regions 33 which are formed on both sides of the stack region 32 in the first direction X and overhang the first semiconductor chip 20 are formed on the second semiconductor chip 30. The other surface of the second semiconductor chip 30 is fixedly bonded to the first semiconductor chip 20 by means of the adhesive member 80 such as a DAF.

A predetermined circuit (not depicted) and second electrode pads 31 are formed on one surface of the second semiconductor chip 30. The plurality of second electrode pads 31 are formed in an array along the short sides of the second semiconductor chip 30 (overhang regions 33), as shown in FIG. 1, the second electrode pads 31 and connection pads 13 being connected by means of the second wires 51, as shown in FIGS. 1 and 2.

As shown in FIGS. 1 and 2, two silicon substrates 40 are stacked on the second semiconductor chip 30. One of the silicon substrates 40 is stacked on the second semiconductor chip 30 in such a way as to lie across the stack region 32 and one of the overhang regions 33. The other silicon substrate 40 is stacked on the second semiconductor chip 30 in such a way as to lie across the stack region 32 and the other overhang region 33. The silicon substrates 40 are fixedly bonded to the second semiconductor chip 30 by means of the adhesive member 80 such as a DAF.

The first wires 50 comprise a conductive metal such as Au, for example, and connect the first electrode pads 21 and the connection pads 13. The second wires 51 comprise a conductive metal such as Au, for example, and connect the second electrode pads 31 and the connection pads 13.

The sealing resin 60 comprises an insulating resin such as an epoxy resin and is formed on one side of the wiring board 10 in order to cover one surface of the first semiconductor chip 20, second semiconductor chip 30, first wires 50, second wires 51 and wiring board 10, as shown in FIG. 2.

The external terminals 70 comprise solder balls which are mounted on the lands 14 of the wiring board 10 in this mode of embodiment. It should be noted that the specific form of the external terminals 70 may be a form other than solder balls.

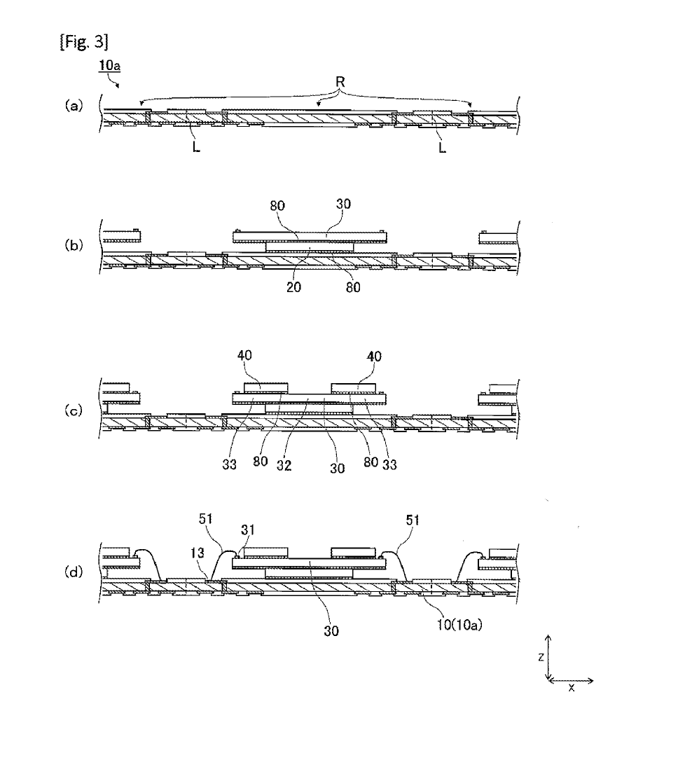

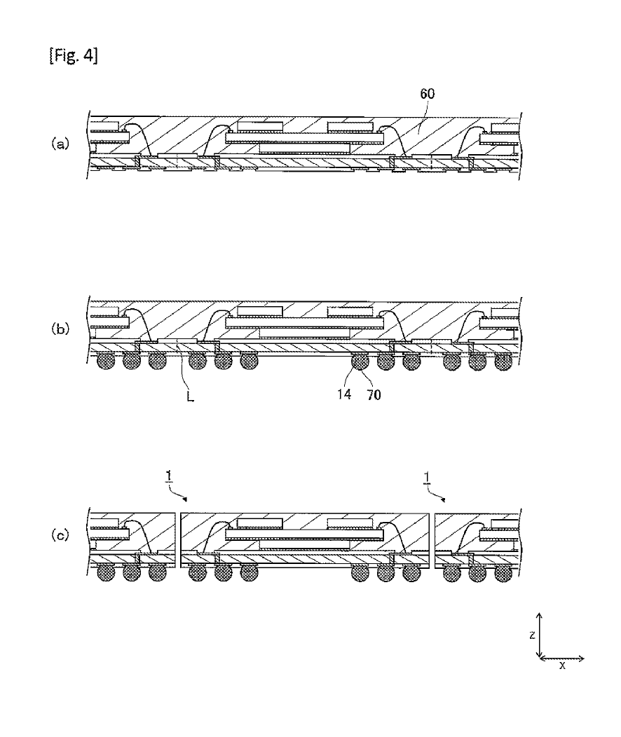

The method for producing the semiconductor device 1 according to the first mode of embodiment will be described below with reference to FIGS. 3 and 4.

First of all, FIG. 3(a) shows a wiring motherboard 10a comprising a plurality of product formation regions R defined by dicing lines L. The product formation regions R are regions that are subsequently cut individually along the dicing lines L to form wiring boards 10. The interlacing film 12, connection pads 13, lands 14 and openings 15 are formed in each product formation region R.

Next, as shown in FIG. 3(b), the first semiconductor chip 20 and the second semiconductor chip 30 are mounted in succession on one surface of the wiring board 10 (wiring motherboard 10a). The first semiconductor chip 20 is fixedly bonded to one surface of the wiring board 10 (wiring motherboard 10a) by means of the adhesive member 80 such as a DAF provided on the other surface of the semiconductor chip 20. The second semiconductor chip 30 is likewise fixedly bonded to one surface of the first semiconductor chip 20 by means of the adhesive member 80 such as a DAF provided on the other surface of the second semiconductor chip 30.

Next, as shown in FIG. 3(c), two silicon substrates 40 are mounted on one surface of the second semiconductor chip 30. The silicon substrates 40 are fixedly bonded to one surface of the second semiconductor chip 30 by means of the adhesive member 80 such as a DAF provided on the other surface of the silicon substrates 40.

Here, as shown in FIG. 3(c), one of the silicon substrates 40 is stacked on the second semiconductor chip 30 in such a way as to lie across the stack region 32 and one of the overhang regions 33, while the other silicon substrate 40 is stacked on the second semiconductor chip 30 in such a way as to lie across the stack region 32 and the other overhang region 33.

Next, as shown in FIG. 3(d), the connection pads 13 of the wiring board 10 (wiring motherboard 10a) and the second electrode pads 31 of the second semiconductor chip 30 are electrically connected using the second wires 51. Furthermore, the connection pads 13 of the wiring board 10 (wiring motherboard 10a) and the first electrode pads 21 of the first semiconductor chip 20 are likewise electrically connected using the first wires 50.

Here, a wire bonding device which is not depicted may be used for the connection employing the wires 50, 51. The connection is formed by means of ball bonding employing ultrasonic thermocompression-bonding, for example. Specifically, the tip ends of the wires 50, 51 which are melted to form balls are ultrasonically thermocompression-bonded onto the electrode pads 21, 31, and the rear ends of the wires 50, 51 are ultrasonically thermocompression-bonded onto the corresponding connection pads 13 in such a way as to describe a predetermined loop shape.

Next, as shown in FIG. 4(a), the sealing resin 60 is formed by integral molding of the wiring board 10 (wiring motherboard 10a) on which are mounted the first semiconductor chip 20, second semiconductor chip 30 and silicon substrates 40. A transfer mold apparatus (not depicted) provided with an upper die (not depicted) and a lower die (not depicted) is used for this integral molding. Specifically, the integral molding is carried out by placing the wiring board 10 (wiring motherboard 10a), which has undergone the die bonding step and the wire bonding step, inside the space formed by the upper die (not depicted) and the lower die (not depicted), and causing a heat-curable epoxy resin or the like to flow into the space.

Next, as shown in FIG. 4(b), the external terminals 70 are mounted on the lands 14 provided on the other surface of the wiring board 10 (wiring motherboard 10a). The external terminals 70 may be mounted using a suction-attachment mechanism (not depicted) provided with a plurality of suction-attachment holes (not depicted) formed in an arrangement corresponding to the plurality of lands 14, for example. In this case, the plurality of external terminals 70 are suction-attached and held by the suction-attachment mechanism (not depicted), and flux is transferred to the external terminals 70 which are held, in order to mount the external terminals 70 in one batch on the lands 14. The area between the external terminals 70 and the lands 14 is then fixedly connected by means of reflow treatment.

Next, as shown in FIG. 4(c), dicing tape (not depicted) is affixed to the sealing resin 60 and supported thereon, and in this state the wiring board 10 (wiring motherboard 10a) and the sealing resin 60 are cut along the dicing lines L using a dicing blade (not depicted). As a result, the wiring board 10 (wiring motherboard 10a) is cut into individual pieces at each product formation region R, after which the individual wiring boards 10 (wiring motherboards 10a) and the sealing resin 60 are picked up from the dicing tape (not depicted) whereby semiconductor devices 1 such as shown in FIGS. 1 and 2 are obtained.

In the semiconductor device 1 according to the first mode of embodiment obtained in this way, the silicon substrates 40 are stacked on the second semiconductor chip 30 in such a way as to lie across the stack region 32 and the overhang regions 33 of the second semiconductor chip 30, and as a result it is possible to increase the essential thickness of the overhang regions 33 of the second semiconductor chip 30 and to increase the rigidity of the overhang regions 33 of the second semiconductor chip 30, so there is no cracking of the chip and no sections which are not wire-bonded, a load or ultrasonic waves can be satisfactorily applied to the second electrode pads 31 formed in the overhang regions 33 of the second semiconductor chip 30, and satisfactory wire bonding can be achieved.

Furthermore, it is no longer necessary to make the second semiconductor chip 30 thick in order to restrict chip cracking or the like, so it is possible to make the second semiconductor chip 30 thinner.

It should be noted that it is necessary to maintain the shape of wire loops 51a of the second wires 51, and the thickness of the resin on the second wires 51 for ensuring stability, so if the thickness of the silicon substrates 40 in the third direction Z is set within the height range of the wire loops 51a and the resin in the third direction Z, the placement of the silicon substrates 40 has no effect on the thickness of the semiconductor device 1 in the third direction Z.

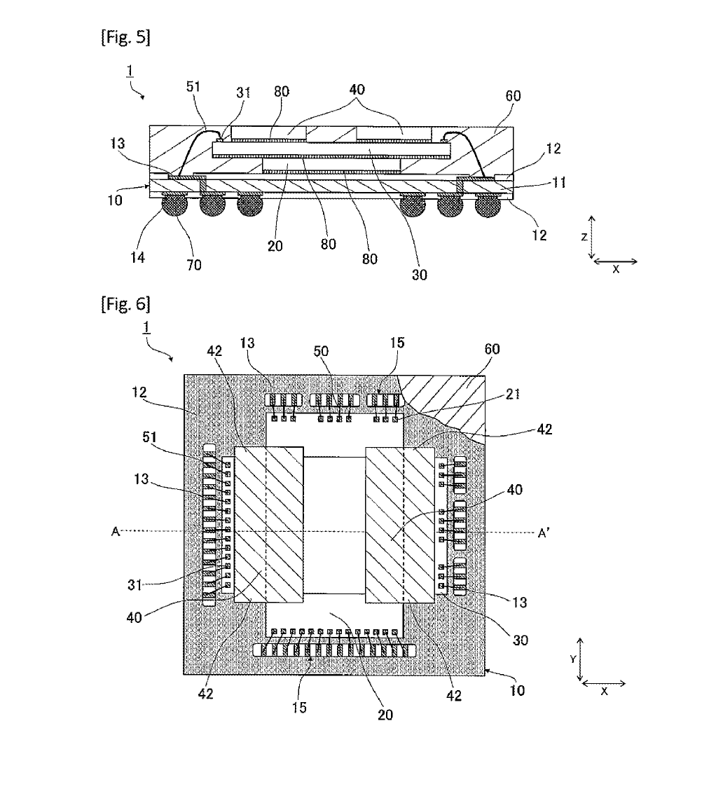

A semiconductor device 1 according to a first variant example of the first mode of embodiment of the present invention will be described next with reference to FIG. 5. The description will relate only to differences with the first mode of embodiment.

According to the first mode of embodiment described above, one surface of the silicon substrates 40 facing the opposite side to the second semiconductor chip 30 side is covered by the sealing resin 60, as shown in FIG. 2.

On the other hand, according to the first variant example of the first mode of embodiment, said one surface of the silicon substrates 40 facing the opposite side to the second semiconductor chip 30 side is not covered by the sealing resin 60 and is exposed to the outside, as shown in FIG. 5.

As a result, according to the first variant example of the first mode of embodiment, the thickness of semiconductor device 1 in the third direction Z can be reduced, while the heat-radiating properties of the semiconductor device 1 can be improved.

A semiconductor device 1 according to a second variant example of the first mode of embodiment of the present invention will be described next with reference to FIG. 6. The description will relate only to differences with the first mode of embodiment.

According to the second variant example of the first mode of embodiment, as shown in FIG. 6, the silicon substrates 40 are mounted on the second semiconductor chip 30 in such a way that both ends of the silicon substrates 40 in the second direction Y overhang the second semiconductor chip 30. That is to say, the silicon substrates 40 have an overhang region 42 which overhangs the second semiconductor chip 30 in the second direction Y, as shown in FIG. 6.

As a result, according to the second variant example of the first mode of embodiment, it is possible to increase the bonding area between the silicon substrates 40 and the second semiconductor chip 30, and it is possible to further increase the rigidity of the overhang regions 33 of the second semiconductor chip 30.

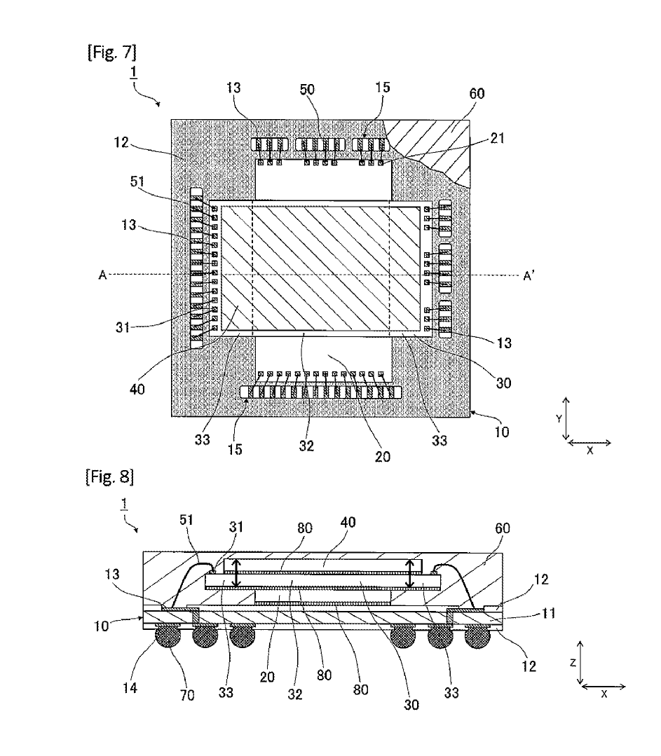

A semiconductor device 1 according to a third variant example of the first mode of embodiment of the present invention will be described next with reference to FIGS. 7 and 8. The description will relate only to differences with the first mode of embodiment.

According to the third variant example of the first mode of embodiment, as shown in FIGS. 7 and 8, a single silicon substrate 40 is placed on the second semiconductor chip 30. Specifically, the silicon substrate 40 is stacked on the second semiconductor chip 30 in such a way as to lie across the stack region 32 and the pair of overhang regions 33 formed on both sides of the stack region 32.

As a result, according to the third variant example of the first mode of embodiment, it is possible to increase the bonding area between the silicon substrate 40 and the second semiconductor chip 30, and it is possible to further increase the rigidity of the overhang regions 33 of the second semiconductor chip 30. Furthermore, a single silicon substrate 40 is required so the production efficiency can be improved in comparison with the first mode of embodiment employing two silicon substrates 40.

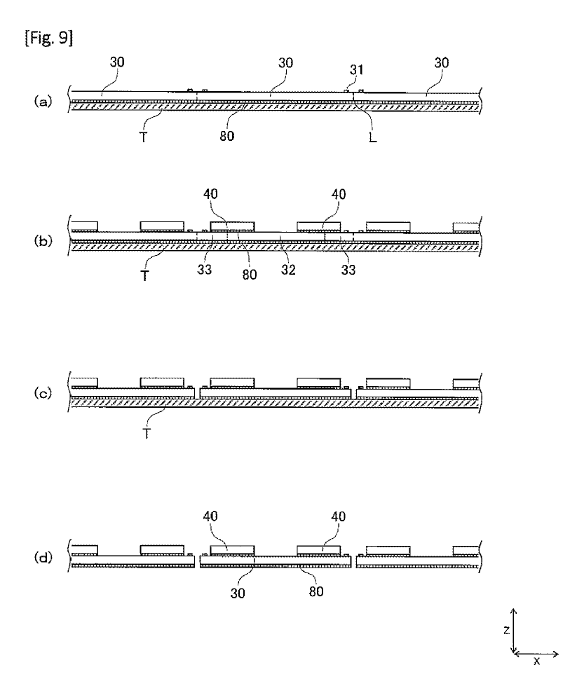

A semiconductor device 1 according to a fourth variant example of the first mode of embodiment of the present invention will be described next with reference to FIG. 9. The description will relate only to differences with the first mode of embodiment.

According to the first mode of embodiment described above, a description was given in relation to an arrangement in which an individual second semiconductor chip 30 is mounted on the first semiconductor chip 20, after which the silicon substrates 40 are mounted on the second semiconductor chip 30, as shown in FIGS. 3(b) and 3(c).

On the other hand, according to the fourth variant example of the first mode of embodiment, a semiconductor wafer on which a plurality of second semiconductor chips 30 are formed is prepared first of all, as shown in FIG. 9(a). The adhesive member 80 is bonded to the semiconductor wafer while dicing tape T is also affixed thereto, and the second electrode pads 31 are formed in advance in predetermined locations.

Next, as shown in FIG. 9(b), a plurality of silicon substrates 40 are mounted at predetermined locations in such a way as to lie across the stack region 32 of the second semiconductor chips 30 (or the portion which will become the stack region 32 to be more precise) and the overhang regions 33 (or portions which will become the overhang regions 33 to be more precise).

Next, as shown in FIG. 9(c), the semiconductor wafer on which the plurality of second semiconductor chips 30 are formed is cut along the dicing lines L.

Next, as shown in FIG. 9(d), a plurality of second semiconductor chips 30 on which the silicon substrates 40 are mounted are obtained by picking up each second semiconductor chip 30 from the dicing tape T.

As a result, according to the fourth variant example of the first mode of embodiment, the chip stacking step for the semiconductor device 1 can be simplified in comparison with the first mode of embodiment as a result of the silicon substrates 40 being mounted at the semiconductor wafer stage.

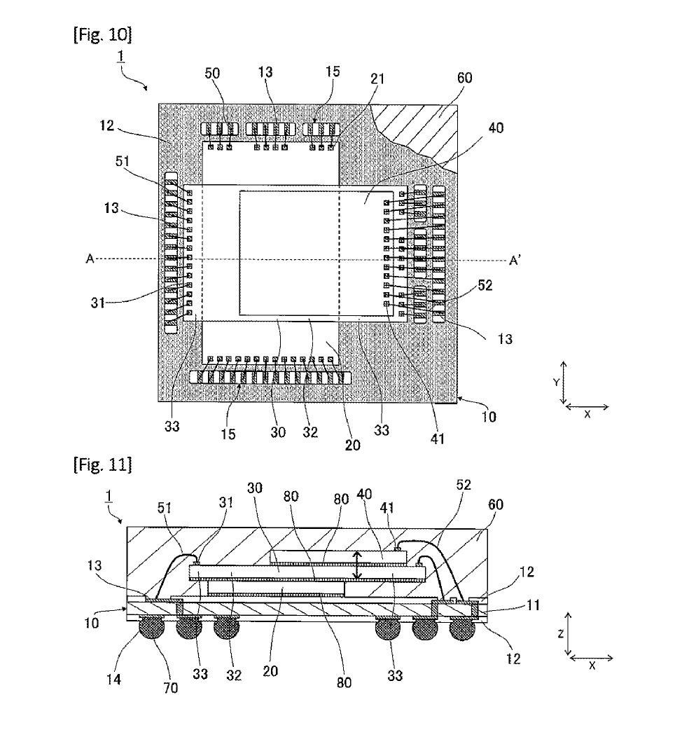

A semiconductor device 1 according to a second mode of embodiment of the present invention will be described next with reference to FIGS. 10 and 11. The description will relate only to differences with the first mode of embodiment.

According to the second mode of embodiment, the silicon substrate 40 is constructed as a third semiconductor chip 40 such as a flash memory chip in which a predetermined circuit is formed.

As shown in FIGS. 10 and 11, a plurality of third electrode pads 41 are formed on the third semiconductor chip 40, and the third electrode pads 41 are electrically connected to the connection pads 13 by means of third wires 52.

It is thus possible to achieve the same effect as in the first mode of embodiment simply by varying the stacking arrangement of the plurality of semiconductor chips 20, 30, 40 in the semiconductor device 1 in which three or more semiconductor chips 20, 30, 40 are mounted, and it is possible to improve the wire bonding properties in the overhang regions 33 of the second semiconductor chip 30 without providing a new silicon substrate 40.

It should be noted that in the second mode embodiment, as shown in FIGS. 10 and 11, the amount of overhang of one of the two overhang regions 33 of the second semiconductor chip 30 (the overhang region 33 on the left in FIGS. 10 and 11) from the first semiconductor chip 20 in the first direction X, is set to a small amount. In this way, when there is a small amount of overhang from the first semiconductor chip 20, in the second mode of embodiment the third semiconductor chip 40 is mounted only on the other of the two overhang regions 33 (the overhang region 33 on the right in FIGS. 10 and 11) because there is little problem in terms of wire bonding properties.

It should be noted that an example was described above in which both ends of the second semiconductor chip 30 in the first direction X overhang the first semiconductor chip 20, but the second semiconductor chip 30 may equally be mounted on the first semiconductor chip 20 in such a way that only one end of the second semiconductor chip 30 in the first direction overhangs the first semiconductor chip 20.

A description was given above of modes of embodiment and variant examples of the invention devised by the present inventors, but the present invention is not limited to these modes of embodiment and variant examples, and it goes without saying that various modifications may be made within a scope that does not depart from the essential point of the invention.

For example, the abovementioned modes of embodiment and variant examples may be suitably combined.

Furthermore, an example was described above in which silicon substrates are stacked on overhang regions in a semiconductor device in which a plurality of rectangular semiconductor chips on which a plurality of electrode pads are arranged on the short sides are stacked crosswise, but the present invention may equally be applied to any semiconductor device provided that an upper-stage semiconductor chip overhangs a lower-stage semiconductor chip.

Furthermore, an example was described above in which silicon substrates are stacked and mounted in the overhang regions of the upper-stage semiconductor chip, but any material may be used provided that such material has the same thermal expansion coefficient as a silicon substrate.

Furthermore, an example was described above in which the present invention is applied to a semiconductor device in which a two-stage memory chip or a two-stage DRAM memory chip and a flash memory chip are stacked, but any combination of semiconductor devices is feasible, such as a logic chip and a memory chip, provided that an upper-stage semiconductor chip overhangs a lower-stage semiconductor chip.

### KEY TO SYMBOLS

1 . . . Semiconductor device
10 . . . Wiring board
10a . . . Wiring motherboard
11 . . . Insulating base material
12 . . . Insulating film
13 . . . Connection pad
14 . . . Land
15 . . . Opening
20 . . . First semiconductor chip
21 . . . First electrode pad
30 . . . Second semiconductor chip
31 . . . Second electrode pad
32 . . . Stack region
33 . . . Overhang region
40 . . . Silicon substrate (reinforcing plate, third semiconductor chip)
41 . . . Third electrode pad
42 . . . Overhang region
50 . . . First wire
51 . . . Second wire
51a . . . Wire loop
52 . . . Third wire
60 . . . Sealing resin
70 . . . External terminal
80 . . . Adhesive member
L . . . Dicing line
R . . . Product formation region
T . . . Dicing tape
X . . . First direction
Y . . . Second direction
Z . . . Third direction

1. A semiconductor device comprising:
a wiring board on which a plurality of connection pads are formed;
a first semiconductor chip mounted on the wiring board;
a second semiconductor chip which is stacked on the first semiconductor chip and comprises a plurality of electrodes;
a reinforcing plate which is stacked on the second semiconductor chip; and
a plurality of wires for electrically connecting the plurality of connection pads and the plurality of electrodes,
the second semiconductor chip comprising a stack region which lies over the first semiconductor chip, and an overhang region which overhangs the first semiconductor chip,
the electrodes being formed in the overhang region, and
the reinforcing plate being stacked on the second semiconductor chip in such a way as to lie across the stack region and the overhang region of the second semiconductor chip.

2. The semiconductor device of claim 1, wherein the reinforcing plate is a silicon substrate.

3. The semiconductor device of claim 1, wherein the connection pads are formed on a surface of the wiring board facing the first semiconductor chip side.

4. The semiconductor device of claim 1, wherein the electrodes of the second semiconductor chip are formed on a surface of the second semiconductor chip facing the reinforcing plate side.

5. The semiconductor device of claim 1, wherein the reinforcing plate is stacked on the second semiconductor chip as a result of being fixedly bonded by means of an adhesive member.

6. The semiconductor device of claim 1, wherein the reinforcing plate is a third semiconductor chip.

7. The semiconductor device of claim 1, comprising sealing resin for covering the first semiconductor chip, the second semiconductor chip and the reinforcing plate is further provided on one surface of the wiring board, and a surface of the reinforcing plate facing the opposite side to the second semiconductor chip side is not covered by the sealing resin and is exposed to the outside.

8. The semiconductor device of claim 1, wherein the overhang region of the second semiconductor chip is formed on both sides of the stack region with the stack region lying therebetween, and the reinforcing plate is stacked on the second semiconductor chip in such a way as to lie across the stack region and the pair of overhang regions formed on both sides of the stack region.

9. The semiconductor device of claim 1, wherein the overhang region of the second semiconductor chip overhangs the first semiconductor chip in a first direction parallel to the wiring board, and the reinforcing plate has an overhang region which overhangs the second semiconductor chip in a second direction parallel to the wiring board and intersecting the first direction.

10. A method for producing a semiconductor device, comprising:
preparing a wiring board formed with a plurality of connection pads;
mounting a first semiconductor chip on the wiring board;
mounting a second semiconductor chip on which electrodes are formed on the first semiconductor chip in such a way that a portion of the second semiconductor chip overhangs the first semiconductor chip;
mounting a reinforcing plate on the second semiconductor chip in such a way as to lie across a stack region of the second semiconductor chip which lies over the first semiconductor chip and an overhang region of the second semiconductor chip which overhangs the first semiconductor chip; and
electrically connecting the plurality of connection pads and the plurality of electrodes by means of wires.
